(19) United States
(12) Patent Application Publication
(10) Pub. No.: US 2026/0113838 A1
(43) Pub. Date: Apr. 23, 2026

(54) CIRCUIT BOARD STRUCTURE

(71) Applicant: MLMTEK Co., Ltd., Taoyuan City (TW)

(72) Inventor: YU-CHIA CHANG, New Taipei City (TW)

(21) Appl. No.: 19/330,775

(22) Filed: Sep. 16, 2025

(30) Foreign Application Priority Data
Oct. 17, 2024 (TW) 113211261

(51) Int. Cl. H05K 1/03; H05K 1/02; H05K 1/11; H05K 1/18

(52) U.S. Cl. CPC H05K 1/0306; H05K 1/0278; H05K 1/116; H05K 1/181; H05K 2201/09263; H05K 2201/09609; H05K 2201/09618

(57) ABSTRACT

A circuit board structure includes a glass substrate, a plurality of conductive penetration structures, a first conductive layer, a first insulating layer, a second conductive layer and a plurality of passive components. The conductive penetration structures are disposed on the rigid substrate of the glass substrate. The first conductive layer is disposed on the glass substrate. The first conductive layer includes a plurality of first conductive traces and a plurality of first conductive patterns. One of the first conductive traces is electrically connected to one of the conductive penetration structures, and one of the first conductive patterns is electrically connected to one of the first conductive traces. The first insulating layer is disposed on the glass substrate to cover the first conductive layer. The second conductive layer is disposed on the first insulating layer, and the second conductive layer includes a plurality of second conductive patterns.

### CROSS-REFERENCE TO RELATED PATENT APPLICATION

This application claims the benefit of priority to Taiwan Patent Application No. 113211261, filed on Oct. 17, 2024. The entire content of the above identified application is incorporated herein by reference.

Some references, which may include patents, patent applications and various publications, may be cited and discussed in the description of this disclosure. The citation and/or discussion of such references are provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a circuit board structure, and more particularly to a circuit board structure using a glass substrate.

### BACKGROUND OF THE DISCLOSURE

In the modern semiconductor industry, the printed circuit board (PCB) can serve as a substrate for carrying various electronic components and conductive traces, and can be widely and extensively used in consumer electronics, medical equipment, industrial equipment, lighting equipment, and automotive and aerospace industries. In the related art, the most common materials for the PCB are glass fiber and resin, and glass material is widely used in electronic devices such as display panels due to its high flatness and excellent heat dissipation capability.

However, a large number of electronic components, such as resistors, capacitors, inductors, power transistors, or packages containing integrated circuits, are usually placed on the PCB, so that the area occupied by the PCB in the horizontal direction is often increased, which is not conducive to the miniaturization of the terminal electronic devices.

### SUMMARY OF THE DISCLOSURE

In response to the above-referenced technical inadequacy, the present disclosure provides a circuit board structure that utilizes a glass substrate.

In order to solve the above-mentioned problems, one of the technical aspects adopted by the present disclosure is to provide a circuit board structure, which includes a glass substrate, a plurality of conductive penetration structures, a first conductive layer, a first insulating layer, a second conductive layer and a plurality of passive components. The glass substrate includes at least one rigid substrate. The conductive penetration structures are disposed in the at least one rigid substrate. The first conductive layer is disposed on a top side of the glass substrate, in which the first conductive layer includes a plurality of first conductive traces and a plurality of first conductive patterns, one of the first conductive traces is electrically connected to one of the conductive penetration structures, and one of the first conductive patterns is electrically connected to one of the first conductive traces. The first insulating layer is disposed on the top side of the glass substrate to cover the first conductive layer. The second conductive layer is disposed on the first insulating layer, and the second conductive layer includes a plurality of second conductive patterns. The passive components are disposed in the glass substrate or on the top side of the glass substrate, and the passive components include the first conductive patterns and the second conductive patterns.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a circuit board structure according to an embodiment of the present disclosure;

FIG. 2 is a schematic top view of a passive component of the circuit board structure according to the embodiment of the present disclosure;

FIG. 3 is a partial schematic cross-sectional view of the circuit board structure according to the embodiment of the present disclosure;

FIG. 4 is a schematic top view of another passive component of the circuit board structure according to the embodiment of the present disclosure;

FIG. 5 is a schematic perspective view of yet another passive component of the circuit board structure according to the embodiment of the present disclosure;

FIG. 6 is a schematic cross-sectional view of the circuit board structure according to another embodiment of the present disclosure;

FIG. 7 is a schematic cross-sectional view of the circuit board structure according to yet another embodiment of the present disclosure; and

FIG. 8 is a schematic view of the circuit board structure including an adhesive layer that is disposed between a first rigid substrate and a second rigid substrate.

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms are illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

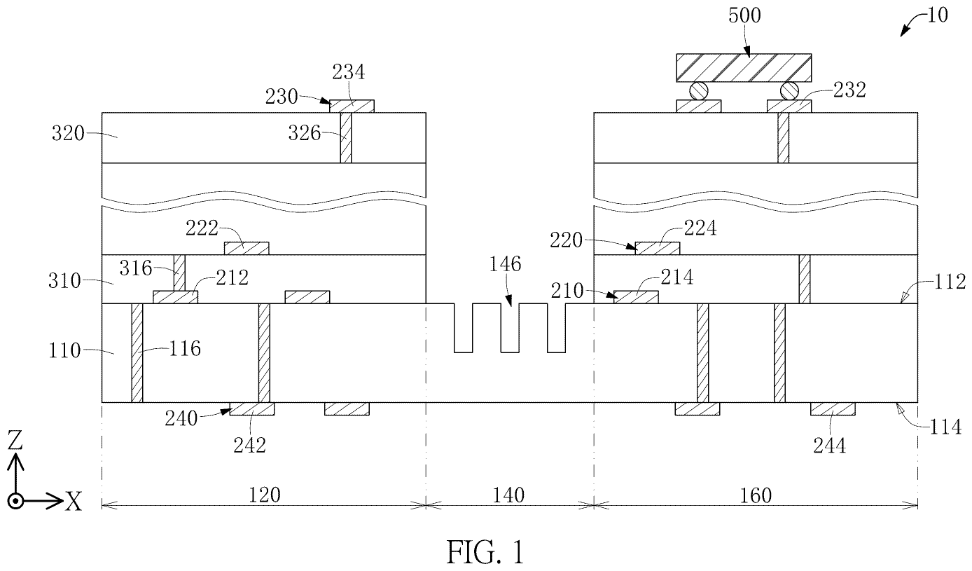

Referring to FIG. 1, which is a schematic cross-sectional view of a circuit board structure according to an embodiment of the present disclosure. As shown in FIG. 1, the circuit board structure 10 may include a glass substrate 110, a first conductive layer 210, a first insulating layer 310 and a second conductive layer 220 from bottom to top of the circuit board structure 10 in sequence. According to one of the feasible embodiments provided by the present disclosure, the glass substrate 110 may include at least one rigid substrate or rigid board (such as a first rigid substrate 120 and/or a second rigid substrate 160) and a first bendable substrate 140 (or a first flexible board). The first rigid substrate 120 and the second rigid substrate 160 are connected together by the first bendable substrate 140 to form a one-piece flexible and hard composite substrate (or a rigid-flex board that is integrally formed).

According to one of the feasible embodiments provided by the present disclosure, the thickness of the first rigid substrate 120, the first bendable substrate 140, and the second rigid substrate 160 can be less than 200 μm (such as any positive integer between 100 μm and 200 μm), and the thickness of the first bendable substrate 140 can be less than the thickness of the first rigid substrate 120 and the second rigid substrate 160. According to one of the feasible embodiments provided by the present disclosure, the glass substrate 110 can be a light-transmitting material, and at least light with a wavelength between 350 nm and 800 nm is allowed to pass through the glass substrate 110 (for example, the ratio of “the intensity of the transmitted light passing through the glass substrate 110” to “the intensity of the incident light entering the glass substrate 110” is greater than 80%, and may be up to 100%). According to one of the feasible embodiments provided by the present disclosure, the glass substrate 110 may be made of any material such as aluminosilicate glass, aluminoborosilicate glass, or barium borosilicate glass. Furthermore, when the subsequent processing temperature is relatively high, it is preferable to use a glass substrate with a strain point above 730° C. By using a glass substrate as a circuit board, the manufactured circuit board can be applied to a light-transmitting device. Compared to the traditional substrate made of glass fiber and resin material, the glass substrate has better thermal conductivity and can provide better heat dissipation (address heat dissipation issues) for electronic components that easily generate heat during operation.

As shown in FIG. 1, a plurality of conductive penetration structures 116 (such as conductive vias) can be disposed in the first rigid substrate 120 of the glass substrate 110 to electrically connect the first conductive layer 210 that can be disposed on the top side 112 of the glass substrate 110, and to electrically connect a plurality of conductive traces that are disposed on the bottom side 114 (or the bottom surface) of the glass substrate 110. The method of forming the conductive penetration structures 116 may include drilling a through hole to pass through a hard board (or a rigid board) by mechanical drilling or laser drilling, and then plating a copper layer on an inner wall and two end portions of the through hole.

According to one of the feasible embodiments provided by the present disclosure, the first bendable substrate 140 may include a plurality of etched portions 146 (or removable portions) to increase the flexibility of the first bendable substrate 140. Depending on different requirements, the etched portions 146 may be recesses or through holes. The top view profile (or the top view outline) of the etched portions 146 can be a curved geometric shape (such as a circle or an ellipse), rather than a polygon or other geometric shape with obvious corners. Therefore, after bending the first bendable substrate 140, stress concentration at specific edges of the etched portions 146 can be avoided, thereby increasing the flexibility of the first bendable substrate 140. According to one of the feasible embodiments provided by the present disclosure, after bending the first bendable substrate 140, the curvature radius of the first bendable substrate 140 can be between 0.5 mm and 5 mm (such as any positive integer between 500 μm and 5000 μm). The glass substrate 110 of the present disclosure is an integrally formed structure including a rigid board (such as the first rigid substrate 120 and/or the second rigid substrate 160) and a bendable board (such as the first bendable substrate 140). It not only avoids complex and high-cost soldering processes (for bonding the flexible board and the rigid board together), but also avoids the problem of alignment deviation (misalignment) or poor adhesion (low adhesion) between two adjacent substrates (such as between the flexible board and the rigid board that are adjacent to each other). In addition, the glass substrate 110 of the present disclosure can realize the flexible function (bendable function) of the circuit board structure 10, so that the circuit board structure 10 can be folded and bent within a predetermined range. The present disclosure can not only reduce the area or volume of the circuit board structure 10 by folding the circuit board structure 10, but also make any electronic product using the circuit board structure 10 provided by the present disclosure have a flexible property (bendable characteristic).

The multiple conductive layers (such as a first conductive layer 210 and a second conductive layer 220) and the multiple insulating layers (such as a first insulating layer 310 and a second insulating layer 320) provided by the present disclosure can be alternately disposed on a rigid board (such as the first rigid substrate 120 and/or the second rigid substrate 160) to form a circuit structure. It is worth noting that the bendable substrate 140 does not have any conductive layers or insulating layers (or only has a small number of conductive layers or insulating layers) to avoid affecting or decreasing the flexibility of the bendable substrate 140.

The first conductive layer 210 can be disposed on the top side 112 (or the top surface) of the glass substrate 110, and the first conductive layer 210 may include a plurality of first conductive traces 212 and a plurality of first conductive patterns 214. The first conductive traces 212 can be used for transmitting electrical signals, and the first conductive patterns 214 can be configured as a portion of a passive component (such as a portion of a resistor structure, a portion of an electrode of a capacitor structure, or a portion of an inductor structure). According to one of the feasible embodiments provided by the present disclosure, the first conductive layer 210 may be made of any metal material (such as aluminum, gold, platinum, silver, nickel, tungsten, chromium, molybdenum, iron, cobalt, copper, or palladium, or an alloy thereof, or a laminate thereof) or a metal oxide (such as indium oxide, indium oxide-tin oxide alloy, indium oxide-zinc oxide alloy or zinc oxide).

The fabrication method for the first conductive layer 210 may include depositing a conductive layer and patterning the conductive layer. For the deposition process, the conductive layer can be formed by evaporation or sputtering. Alternatively, the conductive layer can also be formed by spraying using an inkjet method, printing using a screen printing method, or electroplating. For the patterning process, the first conductive layer 210 can be processed by photolithography and etching to form the first conductive traces 212 and the first conductive patterns 214. According to one of the feasible embodiments provided by the present disclosure, the first conductive traces 212 and the first conductive patterns 214 can be formed simultaneously in a single patterning process. By forming the first conductive traces 212 and the first conductive patterns 214 simultaneously, the manufacturing process of the circuit board structure 10 can be simplified, and the manufacturing time and cost can be reduced.

As shown in FIG. 1, the first insulating layer 310 can be disposed on the top side 112 of the glass substrate 110 to cover the first conductive layer 210. According to one of the feasible embodiments provided by the present disclosure, the material of the first insulating layer 310 may include polyimide (PI), silicon dioxide (SiO₂), silicon nitride (Si₃N₄), or silicon oxynitride (SiON). The first insulating layer 310 can be formed by evaporation, sputtering, blade coating, transfer coating, or any suitable processes.

As shown in FIG. 1, the second conductive layer 220 can be disposed on the first insulating layer 310, and the second conductive layer 220 may include at least one second conductive trace 222 and at least one second conductive pattern 224. The material and formation method of the second conductive layer 220 can be the same as those of the first conductive layer 210, so that the repeated content will not be repeated here.

According to one of the feasible embodiments provided by the present disclosure, a plurality of conductive penetration structures 316 (such as conductive vias) can be disposed in the first insulating layer 310, so that the second conductive trace 222 on the first insulating layer 310 can be electrically connected to the first conductive trace 212 on the glass substrate 110.

The conductive penetration structures 316 can be formed by wet etching, laser etching, or laser etching combined with wet etching to form a through hole, and then copper is electroplated or deposited on the hole wall and two end portions of the through hole, but the present disclosure is not limited thereto.

As shown in FIG. 1, according to one of the feasible embodiments provided by the present disclosure, the circuit board structure 10 may further include a plurality of insulating layers sequentially stacked on the first insulating layer 310 (such as a second insulating layer 320 disposed on the first insulating layer 310 and covering the first insulating layer 310). The number of insulating layers can be determined based on different requirements. Any conductive layers (such as a third conductive layer 230 including at least one third conductive trace 232 and at least one third conductive pattern 234) can be disposed on the second insulating layer 320. The material and fabrication method of the third conductive trace 232 and the third conductive pattern 234 can be the same as those of the second conductive trace 222 and the second conductive pattern 224, so that the repeated content will not be repeated here. A plurality of conductive penetration structures 326 can be disposed in the second insulating layer 320 to electrically connect to the second conductive layer 220 on the first insulating layer 310. The formation method of the conductive penetration structures 326 can be the same as that of the conductive penetration structures 316, so that the repeated content will not be repeated here.

According to one of the feasible embodiments provided by the present disclosure, when each insulating layer (such as the first insulating layer 310 and the second insulating layer 320) is made of an inorganic dielectric material (such as silicon dioxide, silicon nitride, or silicon oxynitride), the thermal conductivity of the inorganic dielectric material is higher than that of the polymer material, so that the present disclosure can provide better heat dissipation effect to avoid heat accumulation in specific areas of the circuit board structure 10.

As shown in FIG. 1, according to one of the feasible embodiments provided by the present disclosure, at least one electronic component 500 can be disposed on the circuit board structure 10 to electrically connect to the circuit board structure 10. The electronic component 500 may be a package including a semiconductor chip (die), and the semiconductor chip may include active components such as transistors. The electronic component 500 may also be a discrete component (or a passive component) such as a resistor, capacitor, or inductor, and the function and number of electronic components 500 can be adjusted according to different functional requirements. Referring to FIG. 1, the electronic component 500 can be disposed on the topmost layer (such as the second insulating layer 320) of the circuit board structure 10 and electrically connected to the third conductive trace 232. The electronic component 500 can be further electrically connected to the first conductive trace 212, or electrically connected to other circuits or components in the circuit board structure 10 through the conductive penetration structures 316 (326) in each insulating layer.

According to one of the feasible embodiments provided by the present disclosure, a stacked structure of insulating layers and conductive layers (not shown in the figures) similar to those on the top side 112 of the glass substrate 110 may be further provided on the bottom side 114 of the glass substrate 110 of the circuit board structure 10, according to different requirements. For example, a fourth conductive layer 240 (such as including a plurality of fourth conductive traces 242 and a plurality of fourth conductive patterns 244) can be disposed on the bottom side 114 of the glass substrate 110. The fourth conductive traces 242 may serve as signal transmission lines. One of the fourth conductive traces 242 can be electrically connected to the first conductive trace 212, the first conductive pattern 214, the second conductive trace 222, or the second conductive pattern 224 through the conductive penetration structures 116 that are electrically connected to the glass substrate 110, but the present disclosure is not limited thereto. The fourth conductive patterns 244 can be configured as a portion (or a part) of a passive component (that is to say, the passive components may include a portion of the fourth conductive patterns 244), so that the passive components can be disposed on the bottom side 114 of the glass substrate 110.

Depending on actual requirements, various passive components can be stacked on the circuit board structure 10, and the passive components can be formed by depositing and patterning conductive layers. For example, the first conductive patterns 214 can be configured or formed as a portion of a resistor structure (also called a resistor), a portion of an electrode of a capacitor structure (also called a capacitor), or a portion of an inductor structure (also called an inductor), respectively. Through photolithography and etching processes, the size of the passive components can be successfully miniaturized or reduced, for example, to the sub-micron or nanometer level. By vertically stacking the passive components, the plane area (or horizontal area) of the circuit board structure 10 can be successfully reduced.

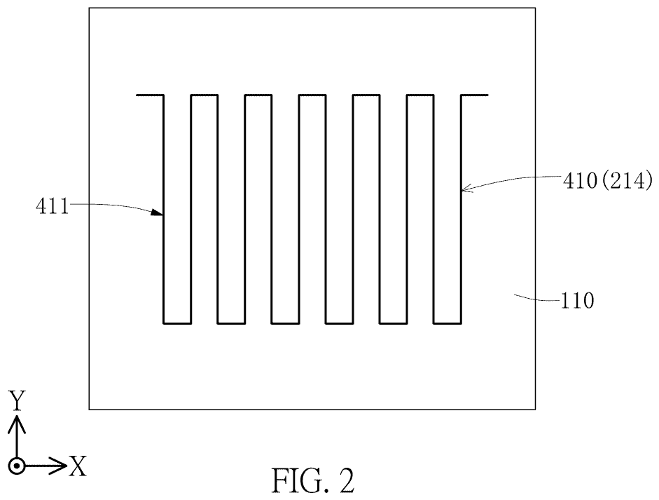

FIG. 2 is a schematic top view of a passive component in the circuit board structure according to an embodiment of the present disclosure. According to one of the feasible embodiments provided by the present disclosure, the passive components disposed on the circuit board structure 10 may include a resistor structure 410, and the resistor structure 410 may include a portion of the first conductive pattern 214 (that is to say, a portion of the first conductive pattern 214 may function as a resistor). The material of the resistor structure 410 can be determined according to actual requirements. For example, a material (such as ruthenium oxide or a carbon film) with a higher resistivity than the conductive layer material can be used as the material of the resistor structure 410. In addition to material selection, the resistance value of the resistor structure 410 can also be increased by lengthening the trace length to meet actual requirements. Referring to FIG. 1 and FIG. 2, the first conductive layer 210 can be patterned to form a planar meandering structure 411 (or a planar zigzag structure), and the planar meandering structure 411 may include a portion of the first conductive pattern 214. It is worth noting that the second conductive layer 220 can be patterned to form a planar meandering structure, and the planar meandering structure may include a portion of the second conductive pattern 224.

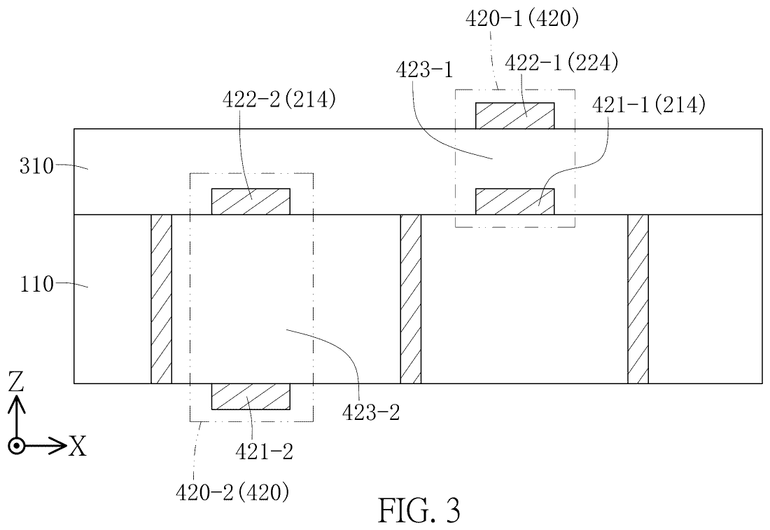

FIG. 3 is a partial schematic cross-sectional view of the circuit board structure according to the embodiment of the present disclosure. As shown in FIG. 3, the passive components disposed on the circuit board structure 10 include a capacitor structure 420 (such as a first capacitor structure 420-1 and/or a second capacitor structure 420-2). The internal structure of each capacitor structure 420 may include a first electrode (421-1 or 421-2), a second electrode (422-1 or 422-2), and a capacitor dielectric layer (423-1 or 423-2).

For the first capacitor structure 420-1, the capacitor dielectric layer 423-1 can be disposed between the first electrode 421-1 and the second electrode 422-1, and the capacitor dielectric layer 423-1 may include a portion of the first insulating layer 310. That is to say, not only the first insulating layer 310 can be used to accommodate the conductive penetration structures (or prevent adjacent conductive lines from directly contacting each other), but also a portion of the first insulating layer 310 can be used as a portion of the capacitor dielectric layer 423-1.

For the second capacitor structure 420-2, the capacitor dielectric layer 423-2 can be disposed between the first electrode 421-2 and the second electrode 422-2, and the capacitor dielectric layer 423-2 may include a portion of the glass substrate 110. That is to say, not only the glass substrate 110 can be used as a substrate, but also a portion of the glass substrate 110 can be used as a portion of the capacitor dielectric layer 423-2.

According to the embodiment as shown in FIG. 3, one of the first electrodes (421-1, 421-2) and the second electrodes (422-1, 422-2) may include a portion of the first conductive pattern 214. In another embodiment of the present disclosure, both the first electrode 421-1 and the second electrode 422-2 may include a portion of the first conductive pattern 214.

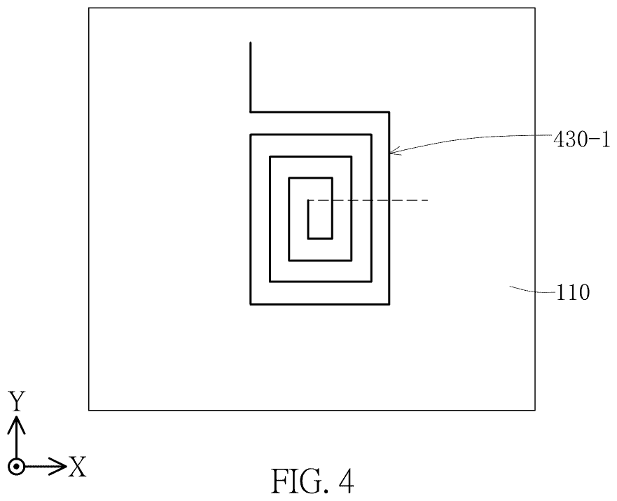

FIG. 4 is a schematic top view of another passive component of the circuit board structure according to the embodiment of the present disclosure. According to one of the feasible embodiments provided by the present disclosure, the passive components disposed on the circuit board structure 10 may include an inductor structure 430-1. As shown in FIG. 4, the inductor structure 430-1 may be a planar coil structure, and the planar coil structure may be a planar coil having a predetermined shape such as a rectangular or circular shape, but the present disclosure is not limited thereto. Referring to FIG. 1 and FIG. 4, the inductor structure 430-1 can be disposed on different conductive layers of the circuit board structure 10 according to different requirements. For example, the inductor structure 430-1 can be formed by a portion of the first conductive pattern 214 or a portion of the second conductive pattern 224.

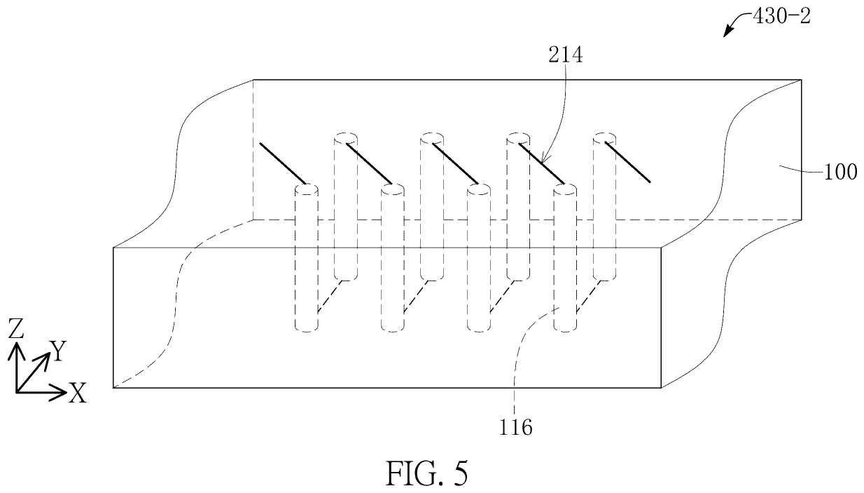

FIG. 5 is a schematic perspective view of yet another passive component of the circuit board structure according to the embodiment of the present disclosure. According to one of the feasible embodiments provided by the present disclosure, the passive components disposed on the circuit board structure 10 may also include an inductor structure 430-2. Referring to FIG. 1 and FIG. 5, the inductor structure 430-2 disposed on the circuit board structure 10 may also be a three-dimensional coil structure. The inductor structure 430-2 may include a portion of the first conductive pattern 214 and a portion of the conductive penetration structure 116. The extension direction of the central axis of the coil structure of the inductor structure 430-2 can be parallel to the surface of the circuit board structure 10.

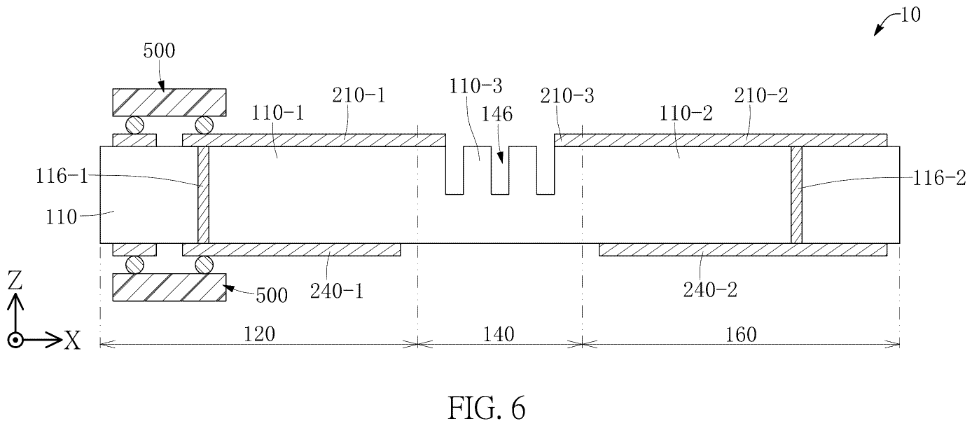

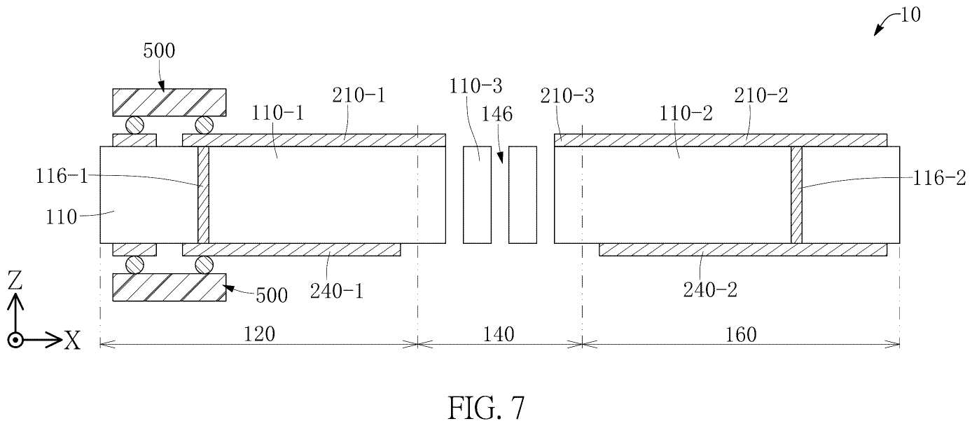

FIG. 6 is a schematic cross-sectional view of the circuit board structure according to another embodiment of the present disclosure, and FIG. 7 is a schematic cross-sectional view of the circuit board structure according to yet another embodiment of the present disclosure. As shown in FIG. 6 or FIG. 7, the present disclosure can also provide a circuit board structure 10, which may include a first rigid substrate 120, a second rigid substrate 160, and a first bendable substrate 140. More particularly, the first rigid substrate 120 may include a first rigid glass substrate 110-1 and a first conductive trace 210-1, and the first conductive trace 210-1 can be disposed on a side (a surface) of the first rigid glass substrate 110-1. The second rigid substrate 160 may include a second rigid glass substrate 110-2 and a second conductive trace 210-2, and the second conductive trace 210-2 can be disposed on a side (a surface) of the second rigid glass substrate 110-2. The first bendable substrate 140 can be connected to the first rigid substrate 120 and the second rigid substrate 160. The first bendable substrate 140 may include a first flexible glass substrate 110-3 and a first connection trace 210-3, and the first connection trace 210-3 can be disposed on a side (a surface) of the first flexible glass substrate 110-3. It should be noted that the first rigid glass substrate 110-1, the second rigid glass substrate 110-2, and the first flexible glass substrate 110-3 may be an integrally formed structure (or a one-piece structure). The first rigid glass substrate 110-1 may include a plurality of conductive penetration structures 116-1, and the second rigid glass substrate 110-2 may include a plurality of conductive penetration structures 116-2. The first conductive trace 210-1, the second conductive trace 210-2, and the first connection trace 210-3 can be electrically connected to each other.

For example, as shown in FIG. 6 or FIG. 7, the first rigid substrate 120 may include a first backside conductive trace 240-1 disposed on another side (another surface) of the first rigid glass substrate 110-1 and opposite to the first conductive trace 210-1, and the first backside conductive trace 240-1 can be electrically connected to the first conductive trace 210-1 through the conductive penetration structures 116-1. Furthermore, the second rigid substrate 160 may include a second backside conductive trace 240-2 disposed on another side (another surface) of the second rigid glass substrate 110-2 and opposite to the second conductive trace 210-2, and the second backside conductive trace 240-2 can be electrically connected to the second conductive trace 210-2 through the conductive penetration structures 116-2. Moreover, at least one electronic component 500 can be bonded on one of the first conductive trace 210-1, the second conductive trace 210-2, and the first connection trace 210-3 by soldering, and another electronic component 500 can be bonded on one of the first backside conductive trace 240-1 and the second backside conductive trace 240-2 by soldering. In addition, the thickness of the first rigid glass substrate 110-1 and the second rigid glass substrate 110-2 can be between 50 μm and 200 μm (such as any positive integer between 50 μm and 200 μm), and the first bendable substrate 140 may include a plurality of etched portions 146 (such as non-through grooves as shown in FIG. 6, or through holes as shown in FIG. 7).

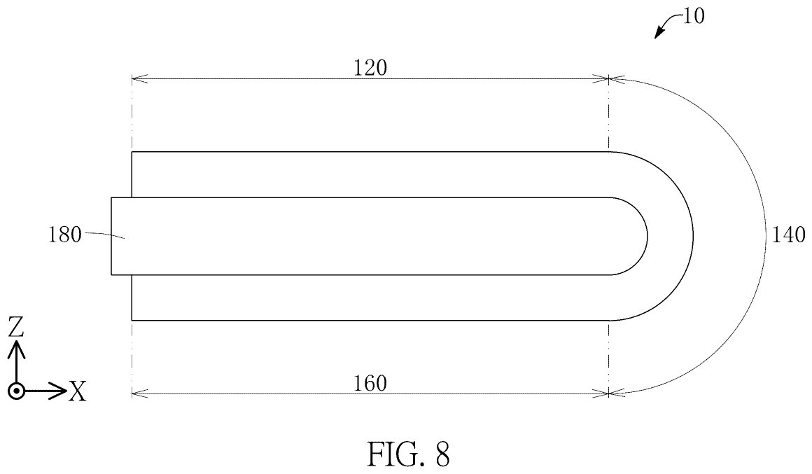

It should be noted that FIG. 8 is a schematic view of the circuit board structure including an adhesive layer that is disposed between a first rigid substrate and a second rigid substrate. Referring to FIG. 6 (or FIG. 7) and FIG. 8, when the first rigid glass substrate 110-1 and the second rigid glass substrate 110-2 are configured to correspond to each other (or face each other) by bending the first bendable substrate 140, the first rigid substrate 120 and the second rigid substrate 160 can be connected together through an adhesive layer 180 that is disposed between the first rigid substrate 120 and the second rigid substrate 160 (or at least one electronic component 500 can be disposed between the first rigid substrate 120 and the second rigid substrate 160). For example, after bending the first bendable substrate 140, the curvature radius (the bending radius) of the first bendable substrate 140 can be between 0.5 mm and 5 mm (such as any positive integer between 500 μm and 5000 μm).

It should be noted that the present disclosure can provide a flexible multilayer circuit board structure 10 that can be configured to vertically integrate or bond the passive components (such as the low-loss and high-frequency passive components) on a glass substrate, and the circuit board structure 10 can be configured as a glass circuit board for high-frequency (high-speed) packaging applications. In particular, the single glass substrate used by the circuit board structure 10 can provide a rigid area and a flexible area at the same time, and the passive components such as resistors, capacitors and inductors can be vertically integrated on the rigid area of the circuit board structure 10. For example, the single glass substrate 110 used by the circuit board structure 10 can be formed into at least one rigid area with a thickness ranging from 80 μm to 200 μm (such as any positive integer between 80 μm and 200 μm), and at least one flexible area with a thickness ranging from 30 μm to 80 μm (such as any positive integer between 30 μm and 80 μm), by an integral molding method. The conductive layers or insulating layers can be alternately stacked on the rigid area (such as the first rigid substrate 120 or the second rigid substrate 160) of the glass substrate 110, and the line width and the line spacing of the conductive layers or the insulating layers can be between 1 μm and 4 μm. The diameter of the through glass via (TGV) of the circuit board structure 10 can be between 10 μm and 50 μm, the flexible area of the glass substrate 110 can be provided with a hole array to disperse stress, and the rigid area of the glass substrate 110 can form a cavity to accommodate the SiPh transceiver chip (with a passive network matched to 50Ω) that can use passive components (such as resistors, inductors, and capacitors) to adjust the impedance of the transmission line to achieve 50Ω impedance matching, reduce signal reflections, and maximize power transmission. More particularly, the specific embodiment and process parameters of the present disclosure are shown as follows. Firstly, the line width and the line spacing of 3 μm can be achieved through 355 nm LDI (Laser Direct Imaging) lithography and copper electroplating, and the microstrip line impedance can be controlled to 55Ω. Furthermore, the through glass vias (TGVs) of the circuit board structure 10 can be drilled by a picosecond laser with a wavelength of 1064 nm, and can be formed by using a Ti/Cu PVD (Physical Vapor Deposition) seed layer and acid electroplating, in which the diameter of the through glass via can be between 10 μm and 50 μm, and the parasitic inductance can be less than 5 pH at 50 GHz. Moreover, the flexible area of the glass substrate 110 has a thickness of 50 μm, which can disperse stress through the hole array formed by a hole density of 25 to 35%, and the change in the conductor resistance in the flexible area is less than 5% after bending 105 times with a curvature of 1 mm. In addition, the SiPh chip is embedded in a deep cavity with a thickness of 250 μm, cooperated with a 1.5 pF MIM (Metal-Insulator-Metal) capacitor and a 1 nH spiral inductor to form a pi-filter (π-filter), achieving |S11|<−18 dB from 45-60 GHz.

In order to make a person of ordinary skill in the art better understand the present disclosure, the present disclosure will be described in detail below with reference to specific examples. These examples are only used to illustrate the present disclosure and should not limit the scope of the present disclosure in any way.

### Example 1: Integrating Capacitor Components on Glass Substrate

1. Substrate Preparation: A high-purity borosilicate glass substrate with a thickness of approximately 0.5 mm and a relative dielectric constant (or a relative permittivity er) of approximately 4.6 can be selected. The glass substrate can be cleaned to remove surface impurities to ensure quality for subsequent processes.
2. Via Fabrication: Laser drilling technology can be used to form vias with a diameter of approximately 100 μm in the glass substrate, with a pitch of approximately 1 mm, and the position of the vias can be determined according to different circuit design requirements.
3. Via Metallization: A copper layer with a thickness of approximately 1 μm can be deposited on the inner wall of each via to form a conductive path by a physical vapor deposition (PVD) method.
4. Electrode Formation: a top electrode pattern and a bottom electrode pattern of the capacitor can be respectively formed on the front and back sides of the glass substrate through photolithography and wet etching processes, and a three-layer structure of molybdenum/aluminum/molybdenum (Mo/Al/Mo) can be used for the electrodes to improve conductivity and reliability.
5. Dielectric Layer Formation: The glass substrate with a thickness of approximately 0.5 mm can be used as a dielectric layer. The required capacitance value can be defined by adjusting the area of the electrode and the thickness of the dielectric layer.
6. Capacitance Calculation and Simulation: The calculated data is shown as follows.

| Electrode Area | Dielectric Layer | Capacitance |
|---|---|---|
| (mm²) | Thickness (mm) | (pF) |
| 1 | 0.5 | 0.81 |
| 1 | 0.3 | 1.35 |
| 1 | 0.1 | 4.05 |
| 2 | 0.5 | 1.62 |
| 2 | 0.3 | 2.70 |
| 2 | 0.1 | 8.10 |
| 5 | 0.5 | 4.05 |
| 5 | 0.3 | 6.75 |
| 5 | 0.1 | 20.25 |

7. Frequency Response Test: The simulation frequency range can be between 1 kHz and 1 GHz. The simulation results show that the capacitance value does not change much with frequency, indicating that the present disclosure can provide a stable electrical performance at a high frequency.
8. Insulating Layer Covering: The electrode patterns can be covered with a polyimide insulating layer having a thickness of approximately 2 μm to protect the electrodes and prevent short circuits.

### Example 2: Integrating Resistor Components on Glass Substrate

1. Substrate Preparation: The same glass substrate as in Example 1 is used.
2. Resistor Material Deposition: A ruthenium oxide thin film with a thickness of approximately 100 nm can be deposited on the surface of the glass substrate surface, which can provide a sheet resistance (Rs) of approximately 100 Ω/sq.
3. Resistor Pattern Formation: The required resistor patterns can be formed through photolithography and ion beam etching processes.
4. Resistance Calculation and Simulation: The calculated data is shown as follows.

| Length (μm) | Width (μm) | Resistance (Ω) |
|---|---|---|
| 500 | 50 | 1000 |
| 500 | 100 | 500 |
| 500 | 200 | 50 |
| 1000 | 50 | 2000 |
| 1000 | 100 | 1000 |
| 1000 | 200 | 500 |
| 2000 | 50 | 4000 |
| 2000 | 100 | 2000 |
| 2000 | 200 | 1000 |

5. Frequency Response Test: The simulation frequency range can be between 1 kHz and 1 GHz. The simulation results show that the resistance value can be increased slightly at a high frequency mainly due to the skin effect, but the increase is within an acceptable range.
6. Electrode Connection: Copper electrodes can be deposited at both ends of each resistor pattern to achieve connection with other circuits through a micromachining technology.
7. Insulating Layer Covering: The entire structure can be covered with a polyimide insulating layer to protect the resistor components and enable the stacking of multiple circuit layers.

### Example 3: Integrating Inductor Components on Glass Substrate

1. Substrate Preparation: The same glass substrate as in Example 1 is used.
2. Planar Spiral Inductor Formation: A copper layer with a thickness of approximately 2 μm can be deposited on the glass substrate surface.
3. Inductor Structure Design and Simulation: Inductor structure parameters may include number of spiral turns (such as 5, 10, 15), line width (such as 10 μm, 20 μm, 50 μm), line spacing (such as 10 μm), and spiral outer diameter (such as 100 μm, 200 μm, 500 μm). The inductance value can be calculated by using electromagnetic simulation software such as Ansys HFSS to perform a 3D simulation of the planar spiral inductor and calculate the self-inductance of the planar spiral inductor. The calculated data is shown as follows.

| Number of Spiral | Line Width | Outer Diameter | Inductance |
|---|---|---|---|
| Turns | (μm) | (μm) | (nH) |
| 5 | 10 | 100 | 0.5 |
| 5 | 20 | 200 | 1.0 |
| 5 | 50 | 500 | 2.5 |
| 10 | 10 | 100 | 1.0 |
| 10 | 20 | 200 | 2.0 |
| 10 | 50 | 500 | 5.0 |
| 15 | 10 | 100 | 1.5 |
| 15 | 20 | 200 | 3.0 |
| 15 | 50 | 500 | 7.5 |

4. Frequency Response Test: The simulation frequency range can be between 10 MHz and 5 GHz. The simulation results show that the inductance value can be decreased slightly with increasing frequency, and the Q-factor (quality factor) of the inductor can be decreased at a high frequency.
5. Inductor Pattern Formation: The planar spiral inductor patterns can be formed through photolithography and wet etching processes.
6. Insulating Layer Covering: The inductor patterns can be covered with an insulating layer to prevent short circuits and protect the inductor components.

### Example 4: Integrated Circuit Performance Test

1. Circuit Design: Basic circuits such as an LC resonant circuit and an RC filter can be provided.
2. Component Parameter Selection: The capacitance, resistance and inductance values can be appropriately selected based on the simulation results.
3. Simulation and Testing: The simulation results of the LC resonant circuit show that the error between the resonant frequency and the theoretical value is less than 2%. The simulation results of the RC low-pass filter show that the filter has good attenuation characteristics at the predetermined cutoff frequency.
4. Result Analysis: The performance of the components is stable, and the circuit is working properly, thus proving the feasibility of the present disclosure.

### Example 5: Reliability Testing

1. Thermal Cycling Test: The test conditions are set to a temperature range between-40° C. and 85° C. for 500 cycles. The test results show that there is no significant change in component performance, and the change rate of capacitance, resistance and inductance values is less than 1%.
2. High Temperature & High Humidity Test: The test conditions are set to a temperature of approximately 85° C. and a relative humidity of approximately 85%, for 1000 hours. The test results show that the component performance is stable, with no obvious aging phenomenon.
3. Mechanical Vibration Test: The test conditions are set to a frequency range between 20 Hz and 2 kHz, with an acceleration of 5 g for 2 hours. The test results show no physical damage and no significant change in electrical performance.

According to the circuit board structure provided by the present disclosure, the passive components (such as resistors, capacitors, inductors) that originally occupied the outermost side area of the circuit board structure can be arranged in different insulating layers within the circuit board structure, thereby reducing the use of the top side area of the circuit board structure and increasing the flexibility of the circuit layout and the electronic component configuration on the circuit board. Furthermore, the conductive patterns and the conductive traces (such as the first conductive traces or the second conductive traces) can be formed simultaneously through photolithography and etching processes, so that the manufacturing process can be simplified, the manufacturing costs can be reduced, and the size of the passive components can be successfully miniaturized. In addition, the conductive patterns and the conductive traces can be vertically stacked between multiple insulating layers, thereby successfully reducing the planar area of the circuit board structure (i.e., reducing the horizontal extension area of the circuit board structure).

Through the above-mentioned embodiments, it can be seen that the circuit board structure of the present disclosure successfully integrates the passive components such as capacitors, resistors, and inductors on the glass substrate. The passive components integrated on the circuit board structure of the present disclosure have stable performance and reliable manufacturing process and can then be widely used in high-frequency electronic equipment.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A circuit board structure, comprising:
a glass substrate including at least one rigid substrate;
a plurality of conductive penetration structures disposed in the at least one rigid substrate;
a first conductive layer disposed on a top side of the glass substrate, wherein the first conductive layer includes a plurality of first conductive traces and a plurality of first conductive patterns, one of the first conductive traces is electrically connected to one of the conductive penetration structures, and one of the first conductive patterns is electrically connected to one of the first conductive traces;
a first insulating layer disposed on the top side of the glass substrate to cover the first conductive layer;
a second conductive layer disposed on the first insulating layer, wherein the second conductive layer includes a plurality of second conductive patterns; and
a plurality of passive components disposed in the glass substrate or on the top side of the glass substrate, wherein the passive components include the first conductive patterns and the second conductive patterns.

2. The circuit board structure according to claim 1,
wherein the at least one rigid substrate includes two rigid substrates, the glass substrate includes a bendable substrate, and the two rigid substrates and the bendable substrate are configured as an integrally formed structure;
wherein the first insulating layer includes a plurality of conductive penetration structures, and one of the conductive penetration structures is electrically connected to the first conductive layer;
wherein the circuit board structure further includes at least one active component disposed on a top side of the first insulating layer and electrically connected to the second conductive layer; and
wherein the first conductive patterns are configured to form a portion of a resistor structure, a portion of an electrode of a capacitor structure, or a portion of an inductor structure.

3. The circuit board structure according to claim 1, wherein one of the passive components is configured as a resistor, the resistor includes a planar meandering structure disposed on the top side of the glass substrate, and the planar meandering structure includes a portion of the first conductive patterns or a portion of the second conductive patterns.

4. The circuit board structure according to claim 1, wherein one of the passive components is configured as a capacitor, the capacitor includes a first electrode, a second electrode and a capacitor dielectric layer, one of the first electrode and the second electrode includes a portion of the first conductive patterns, the capacitor dielectric layer is disposed between the first electrode and the second electrode, and the capacitor dielectric layer includes a portion of the first insulating layer.

5. The circuit board structure according to claim 1, wherein one of the passive components is configured as an inductor, the inductor includes a planar coil structure, and the planar coil structure includes a portion of the first conductive patterns or a portion of the second conductive patterns.

6. The circuit board structure according to claim 1, wherein one of the passive components is configured as an inductor, the inductor includes a three-dimensional coil structure, and the three-dimensional coil structure includes a portion of the conductive penetration structures and a portion of the first conductive patterns.

7. The circuit board structure according to claim 1, further comprising a fourth conductive layer disposed on a bottom side of the glass substrate, wherein the fourth conductive layer includes a plurality of fourth conductive traces and a plurality of fourth conductive patterns, one of the fourth conductive traces is electrically connected to another one of the conductive penetration structures, one of the fourth conductive patterns is electrically connected to one of the fourth conductive traces, and the passive components include the fourth conductive patterns.

8. A circuit board structure, comprising:
a first rigid substrate including a first rigid glass substrate and a first conductive trace disposed on a side of the first rigid glass substrate;
a second rigid substrate including a second rigid glass substrate and a second conductive trace disposed on a side of the second rigid glass substrate; and
a first bendable substrate connected to the first rigid substrate and the second rigid substrate, wherein the first bendable substrate includes a first flexible glass substrate and a first connection trace disposed on a side of the first flexible glass substrate;
wherein the first rigid glass substrate, the second rigid glass substrate, and the first flexible glass substrate are configured as an integrally formed structure, the first rigid glass substrate includes a first plurality of conductive penetration structures, and the second rigid glass substrate includes a second plurality of conductive penetration structures;
wherein the first conductive trace, the second conductive trace, and the first connection trace are electrically connected to each other; and
wherein, when the first bendable substrate is bent, a radius of curvature of the first bendable substrate is between 0.5 mm and 5 mm.

9. The circuit board structure according to claim 8,
wherein a thickness of any one of the first rigid glass substrate and the second rigid glass substrate is between 50 μm and 200 μm;
wherein the first bendable substrate includes a plurality of etched portions;
wherein at least one electronic component is bonded on one of the first conductive trace, the second conductive trace, and the first connection trace;
wherein, when a top side of the first rigid glass substrate and a top side of the second rigid glass substrate are configured to face each other by bending the first bendable substrate, the at least one electronic component is located between the first rigid glass substrate and the second rigid glass substrate;
wherein the first rigid substrate includes a first backside conductive trace disposed on another side of the first rigid glass substrate and opposite to the first conductive trace, and the first backside conductive trace is electrically connected to the first conductive trace through the conductive penetration structures;
wherein the second rigid substrate includes a second backside conductive trace disposed on another side of the second rigid glass substrate and opposite to the second conductive trace, and the second backside conductive trace is electrically connected to the second conductive trace through the conductive penetration structures; and
wherein another electronic component is bonded on one of the first backside conductive trace and the second backside conductive trace.

10. A circuit board structure, comprising:
a first rigid substrate including a first rigid glass substrate and a first conductive trace disposed on a side of the first rigid glass substrate, wherein the first rigid glass substrate includes a plurality of conductive penetration structures electrically connected to the first conductive trace;
a second rigid substrate including a second rigid glass substrate and a second conductive trace disposed on a side of the second rigid glass substrate;
a first bendable substrate connecting to the first rigid substrate and the second rigid substrate, wherein the first bendable substrate includes a first flexible glass substrate and a first connection trace disposed on a side of the first flexible glass substrate, and a radius of curvature of the first bendable substrate is between 0.5 mm and 5 mm;
at least one electronic component disposed between the first rigid substrate and the second rigid substrate, wherein the at least one electronic component is bonded on the first conductive trace or the second conductive trace; and
an adhesive layer disposed between the first rigid substrate and the second rigid substrate to connect the first rigid substrate with the second rigid substrate;
wherein the first rigid glass substrate, the second rigid glass substrate, and the first flexible glass substrate are configured as an integrally formed structure; and
wherein the first conductive trace, the second conductive trace, and the first connection trace are electrically connected to each other.
